(19) United States
(12) Patent Application Publication
(10) Pub. No.: US 2014/0302690 A1
(43) Pub. Date: Oct. 9, 2014

(54) CHEMICAL LINKERS TO IMPART IMPROVED MECHANICAL STRENGTH TO FLOWABLE FILMS

(71) Applicant: Applied Materials, Inc., Santa Clara, CA (US)

(72) Inventors: Brian S. Underwood, Santa Clara, CA (US); Abhijit B. Mallick, Palo Alto, CA (US); Nitin K. Ingle, San Jose, CA (US)

(73) Assignee: Applied Materials, Inc., Santa Clara, CA (US)

(21) Appl. No.: 14/019,861

(22) Filed: Sep. 6, 2013

Related U.S. Application Data
(60) Provisional application No. 61/808,438, filed on Apr. 4, 2013.

(51) Int. Cl. H01L 21/02

(52) U.S. Cl. CPC H01L 21/02263
USPC 438/787

(57) ABSTRACT

Methods forming a low-κ dielectric material on a substrate are described. The methods may include the steps of producing a radical precursor by flowing an unexcited precursor into a remote plasma region, and reacting the radical precursor with a gas-phase silicon precursor to deposit a flowable film on the substrate. The gas-phase silicon precursor may include at least one silicon-and-oxygen containing compound and at least one silicon-and-carbon linker. The flowable film may be cured to form the low-κ dielectric material.

### CROSS-REFERENCES TO RELATED APPLICATIONS

This application claims the benefit of U.S. Provisional Application No. 61/808,438, filed Apr. 4, 2013, entitled “Chemical Linkers to Impart Improved Mechanical Strength to Flowable.” The entire disclosure of which is hereby incorporated by reference for all purposes.

### BACKGROUND

Semiconductor device geometries have dramatically decreased in size since their introduction several decades ago. Modern semiconductor fabrication equipment routinely produce devices with 45 nm, 32 nm, and 28 nm feature sizes, and new equipment is being developed and implemented, to make devices with even smaller geometries. The decreasing feature sizes result in structural features on the device having decreased spatial dimensions. The widths of gaps and trenches on the device narrow to a point where the aspect ratio of gap depth to its width becomes high enough to make it challenging to fill the gap with dielectric material. The depositing dielectric material is prone to clog at the top before the gap completely fills, producing a void or seam, in the middle of the gap.

Over the years, many techniques have been developed to avoid having dielectric material clog the top of a gap, or to “heal” the void or seam that has been formed. One approach has been to start with highly flowable precursor materials that may be applied in a liquid phase to a spinning substrate surface (e.g., Spin-On-Dielectric (SOD) deposition techniques). These flowable precursors can flow into and fill very small substrate gaps without forming voids or weak seams. However, once these highly flowable materials are deposited, they have to be hardened into a solid dielectric material.

In many instances, the hardening includes a heat treatment to remove carbon and hydroxyl groups from the deposited material to leave behind a solid dielectric such as silicon oxide. Unfortunately, the departing carbon and hydroxyl species often leave behind pores in the hardened dielectric that reduce the quality of the final material. In addition, the hardening dielectric also tends to shrink in volume, which can leave cracks and spaces at the interface of the dielectric and the surrounding substrate. In some instances, the volume of the hardened dielectric can decrease by 40% or more.

SOD techniques can also encounter difficulties when feature sizes decrease to a point where the liquids deposited on the substrate can bend and break trench walls patterned into the substrate. For example, high-aspect trench sidewalls, formed by substrate columns having a thickness less than 100 nm, may lean or crack under the surface tension of liquid deposition chemicals. Thus, there is a need for gas phase deposition techniques that can fill a high-aspect ratio gap with dielectric materials without subjecting them to bulk liquid.

The decreasing widths separating structures on the substrate also make the devices increasing sensitive to the electrical properties of the dielectric materials that fill the gaps between these structures. Materials with higher dielectric constants (i.e., higher-κ value) create more parasitic capacitance that can increase RC delay, require more current, and increase signal cross-talk. Thus, a number of low-κ dielectric materials have been developed to reduce this parasitic capacitance, including fluorinated silicon oxides, and carbon-doped silicon oxides.

Carbon-doped silicon oxide dielectric materials are of particular interest because of the variety of precursors and tuneability of the deposition processes. Unfortunately, the problems with mechanical strength and dimensional stability that affect low-κ carbon-doped silicon oxide depositions in SOD can also be a problem with gas-phase depositions. Thus, there is a need to develop gas-phase deposition techniques for depositing low-κ materials with improved mechanical properties. This and other issues are address by the present application.

### BRIEF SUMMARY

Gas-phase processes for forming low-κ dielectric materials with increased mechanical strength on a patterned substrate surface are described. These processes include the deposition of a flowable dielectric material that is formed on the substrate from the reactive combination of an activated oxygen-containing precursor and a silicon precursor. The silicon precursor includes one more compounds with Si—O bonds (e.g., siloxane, organosilicates, etc.) and one or more linkers with Si—C bonds. The linker provides increased strength an ridigity to final low-κ dielectric material formed after curing the flowable dielectric material.

Embodiments of the invention include methods forming a low-κ dielectric material on a substrate. The methods may include the steps of producing a radical precursor by flowing an unexcited precursor into a remote plasma region, and reacting the radical precursor with a gas-phase silicon precursor to deposit a flowable film on the substrate. The gas-phase silicon precursor may include at least one silicon-and-oxygen containing compound and at least one silicon-and-carbon linker. The flowable film may be cured to form the low-κ dielectric material.

Additional embodiments and features are set forth in part in the description that follows, and in part will become apparent to those skilled in the art upon examination of the specification or may be learned by the practice of the invention. The features and advantages of the invention may be realized and attained by means of the instrumentalities, combinations, and methods described in the specification.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a flowchart illustrating selected steps in a method of forming a low-κ dielectric material on a substrate.

FIG. 2 shows a substrate processing system according to embodiments of the invention.

FIG. 3A shows a substrate processing chamber according to embodiments of the invention.

FIG. 3B shows a gas distribution showerhead according to embodiments of the invention.

### DETAILED DESCRIPTION

The present methods may be used to deposit a carbon-containing flowable dielectric material on a substrate and form it into a low-κ dielectric film with improved mechanical properties. The flowable dielectric material is deposited by a gas-phase flowable chemical vapor depostion (FCVD) of reactive precurors that may be subsequently cured to form the low-κ dielectric film. The reactive precursors include a silicon precursor that has a combination of one or more silicon-and-oxygen containing compounds and at least one silicon-and-carbon containing linker, which imparts increased mechanical strength to the low-κ dielectric film.

The low-κ film may be a carbon-containing silicon oxide film (SiOₓ) or silicon-oxygen-carbon film (SiOC). The silicon oxide components are believed to provide a lattice framework for the dielectric material while the added carbon lowers the dielectric constant from that of pure silicon oxide (about 3.9) as well as provide stiffness and mechanical strength to the film.

### Exemplary Deposition Methods

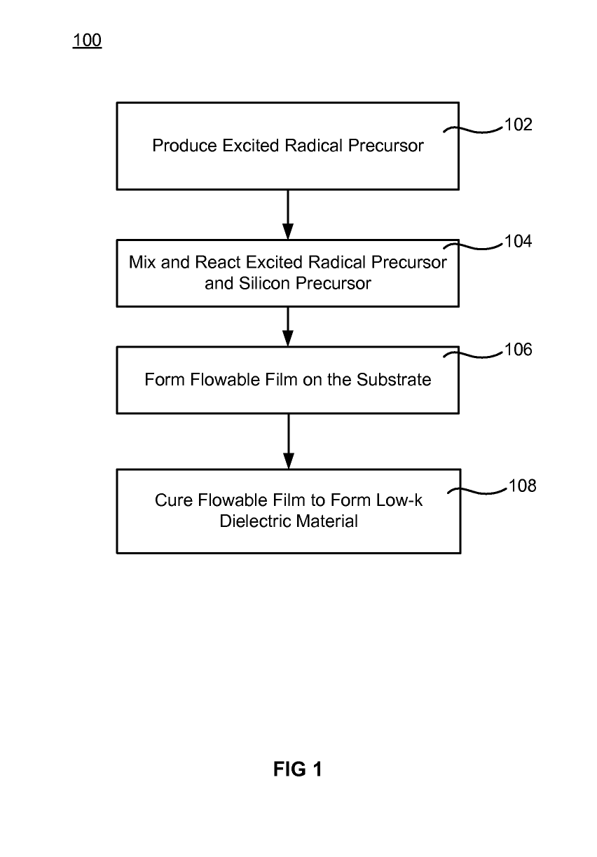

Referring now to FIG. 1, a flowchart is shown with selected steps in a method 100 of forming a low-κ dielectric material on a substrate. The method 100 includes the step of producing a radical precursor by flowing an unexcited precursor into a remote plasma region 102. The radical precursor may be an oxygen-containing precursor such as molecular oxygen (O₂), ozone (O₃), hydroxyl precursors such as water (H₂O) and/or hydrogen peroxide (H₂O₂), nitrogen-oxygen precusors such as N₂O, NO, and NO₂, and carbon-oxygen precursors such as carbon monoxide (CO) and carbon dioxide (CO₂), among others. It should be appreciated that less stable oxygen-containing precursors like ozone and hydrogen peroxide are supplied as mixtures with more stable species like molecular oxygen (O₂) and water (H₂O), respectively.

The oxygen-containing precursor is energized to produce a radical precursor that can react with the silicon precusor to deposit a flowable film on the exposed portions of the substrate. The radical precursor may be generated in a remote plasma system (RPS) positioned outside the depostion region, and in may instances outside the deposition chamber. The RPS unit exposes the oxygen-containing precursor to a plasma that dissociates the precursor into the radical precursor and other products.

Typically, the oxygen-containing precursor is mixed with a more stable carrier gas such as helium, argon, molecular nitrogen, etc. The concentration of the radical species may be adjusted by the intensity of the plasma in the RPS unit as well as the degree to which the oxygen-containing precursor is diluted in a carrier gas. The oxygen-containing precursor may be flowed into the remote plasma region at a flow rate between 10 sccm and 2000 sccm, between 20 sccm and 1000 sccm, or between 30 sccm and 300 sccm in disclosed embodiments.

The radical precursor generated from the oxygen-containing precursor may travel through an isolated conduit until it reaches a reaction region where in can mix and react with the silicon precursor 104. The isolated conduit may include a set of channels in a mulitchannel showerhead (e.g., a dual-zone showerhead) that keep the radical precursor isolated from gases traveling through other sets of channels in the showerhead. The isolated gases emerging from their separate channels in the showerhead may mix in a reaction region in contact with the substrate. In some instances the gases mixing in the reaction region may be further energized by a plasma formed in the reaction region, while in other instances no additional plasma is generated in the reaction region.

The silicon precursor that reacts with the radical precursor may include one or more silicon-and-oxygen containing compounds and at least one silicon-and-carbon linker. The silicon-and-oxygen containing compounds may include siloxanes and/or silicates, among other compounds. Specific examples may include tetramethylorthosilicate (TMOS) and tetraethylorthosilicate (TEOS), among other silicates; as well as octamethyltrisiloxane (OMTS), octamethylcyclotetrasiloxane (OMCTS), and tetramethylcyclotetrasiloxane (TOMCATS), among other siloxanes.

Exemplary silicon-and-carbon linkers may also include compounds with the following structures:

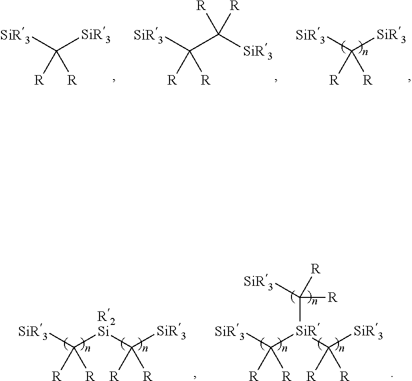

wherein R may each independently be an alkyl moiety, a silyl moiety, or a hydrogen (H) moiety;
R′ may each independly be an alkyl moiety, a silyl moiety, an alkoxyl moiety, or a hydrogen moiety; and
each n may independently be a whole number from 0 to 10, with at least one n value being greater than 0.

Exemplary silicon-and-carbon linkers may further include compounds with the following structures:

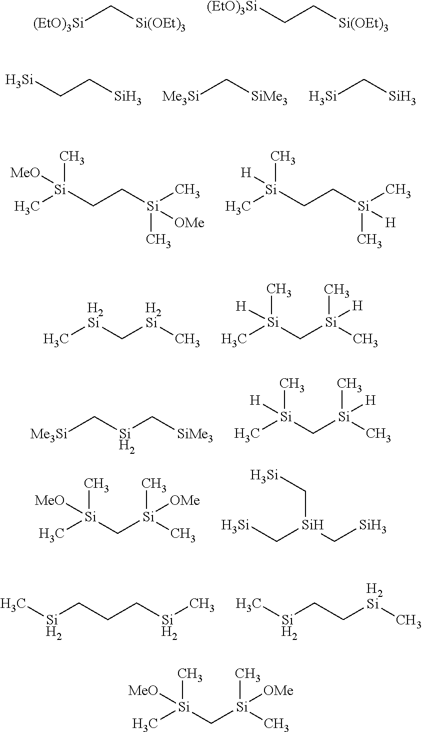

Specific examples of the silicon-and-carbon linkers may also include organosilicon compounds such as 1,3,5-trisilapentane, 1,4,7-trisilaheptane, disilacyclobutane, trisilacyclohexane, 1,4-disilabutane, disilacyclohexane, disilacyclopentane, and disilapropane, among other organosilicon compounds.

The silicon-and-carbon linkers may also include a homocyclic or heterocyclic ring structure. For example, the ring may include both carbon and silicon atoms in a four, five, six, seven, eight, nine, etc., membered ring. They may also include ring structures where the backbone of the ring is made of carbon having silicon moieties attached thereto. It may also include bicyclo ring structures, where two rings are attached to each other.

Exemplary silicon-and-carbon linkers that include cyclic ring structures may include the follow structures, wherein each R may independly represent an alkyl group, a silyl group, or a hydrogen group, and each R′ may independetly represent a hydrogen group (—H), an alkyl group (—CₙH₂ₙ₊₂, where n is an integer from 1 to 4), a silyl group (—SiR₃), or an alkoxyl group (—OMe, —OEt, etc):

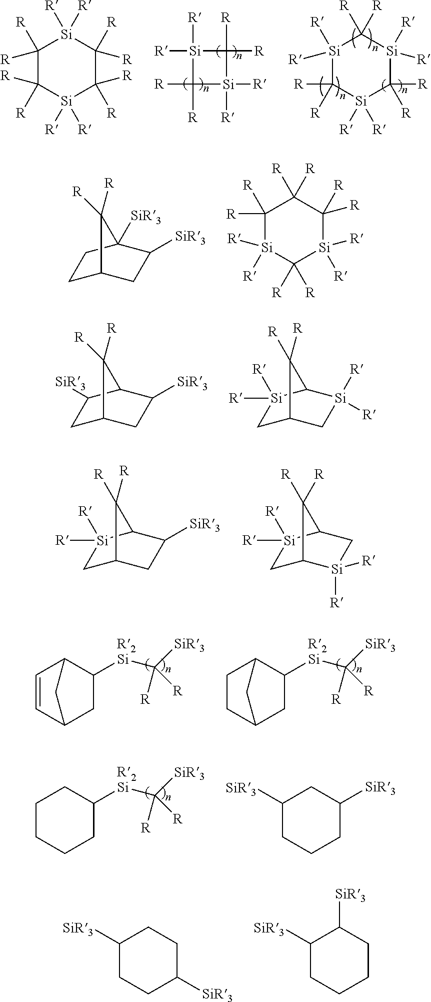

The silicon precursor may also include additional silicon-containing compounds such a silanes (e.g., SiₙH₂ₙ₊₂, n is an integer from 1 to 8), nitrogen-substituted silicon compounds, and halogen-substituted silicon compounds, among other silicon precursors. Examples of these silicon precursors include the following compounds:

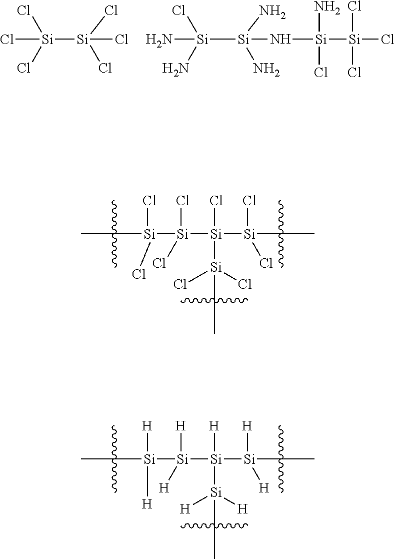 [SMILES: Cl[Si](Cl)(Cl)[Si](Cl)(Cl)Cl ; N[Si](N)(Cl)[Si](N)(N)N[Si](N)(Cl)[Si](Cl)(Cl)Cl ; *[Si](Cl)(Cl)[Si](Cl)(Cl)[Si](Cl)([Si](*)(Cl)Cl)[Si](*)(Cl)Cl ; *[SiH2][SiH2][SiH]([SiH2]*)[SiH2]*]

In some embodiments, the silicon precursor may also include organosilanes and silicon-carbon-oxygen containing compounds. Examples of organosilanes may include alkyl silanes such as methylsilanes (e.g., monomethylsilane, dimethylsilane, trimethylsilane, tetramethylsilane), ethylsilanes, propylsilanes, butylsilanes, etc.

Many silicon precursors are in a liquid state at room temperature and delivered to the reaction region of the deposition chamber with the aid of a carrier gas. Exemplary carrier gases include helium, argon, and nitrogen (N₂), and mixtures thereof, among others. In some instances, the carrier gases may include more reactive gases such as water vapor (H₂O), oxygen (O₂), ammonia (NH₃) and/or molecular hydrogen (H₂), depending on whether an oxidative or reducing atmosphere is desired in the reaction zone.

The silicon precursor may be supplied in the source of a gas or a liquid. The silicon containing precursor may be flowed directly into the substrate processing region at a flow rate between 10 sccm and 2000 sccm, between 20 sccm and 1000 sccm, or between 30 sccm and 300 sccm in embodiments of the invention. The silicon precursor may be flowed directly into the substrate processing region (with the assistance of a carrier gas) at a flow rate between 0.1 milligrams per minute and 2000 milligrams per minute, between 0.3 milligrams per minute and 1000 milligrams per minute or between 0.5 milligrams per minute and 100 milligrams per minute in disclosed embodiments.

When the radical precursor and silicon precursor mix and react in the reaction zone, they form a flowable silicon-oxygen-carbon containing film on exposed portions of the substrate 106. The temperature in the reaction region of the deposition chamber may be low (e.g., less than 100° C.) and the total chamber pressure may be about 0.1 Torr to about 10 Torr (e.g., about 0.5 to about 6 Torr, etc.) during the deposition of the silicon-carbon-oxygen film. The temperature may be controlled in part by a temperature controlled pedestal that supports the substrate. The pedestal may be thermally coupled to a cooling/heating unit that adjust the pedestal and substrate temperature to, for example, about 0° C. to about 150° C.

The flowable film may be deposited on exposed planar surfaces a well as into gaps. The deposition thickness may be about 50 Å or more (e.g., about 100 Å, about 150 Å, about 200 Å, about 250 Å, about 300 Å, about 350 Å, about 400 Å, etc.). The flowable film includes silicon, carbon, oxygen and hydrogen. In some embodiments, the flowable film may contain nitrogen and/or halogens while in other embodiments the film may be substantially free of nitrogen and/or halogens.

The flowability of the initially deposited flowable film may be due to a variety of properties which result from mixing an radical oxygen precursor with the silicon-and-carbon-containing precursor. These properties may include significant hydrogen (—Si—H) and hydroxyl (—Si—OH) components in the initially deposited flowable film as well as the presence of carbon. The flowability does not rely on a high substrate temperature, therefore, the initially-flowable film may fill gaps even on relatively low temperature substrates. During the formation of the flowable film, the substrate temperature may be below or about 400° C., below or about 300° C., below or about 200° C., below or about 150° C. in embodiments of the invention. In a preferred embodiment, the substrate temperature is below or about 100° C. during formation of the flowable film.

When the flowable film reaches a desired thickness, the process effluents may be removed from the substrate-processing region and the flow of radical-oxygen into the substrate processing region may be stopped. These process effluents may include any unreacted oxygen-containing and silicon-and-carbon-containing precursors, diluent and/or carrier gases, and reaction products that did not deposit on the substrate. The process effluents may be removed by evacuating the deposition chamber and/or displacing the effluents with non-deposition gases in the deposition region.

As the deposition of the flowable film is completed, it may be cured 108 to form the low-κ dielectric material. Curing techniques may include exposing the flowable film to UV light and/or an e-beam. They may also include thermal curing at elevated temperature, microwave curing, plasma curing, and/or neutral beam curing. In some embodiments, the curing step may be performed in an appropriately configured deposition chamber, or alternatively the substrate may be transferred to another chamber for curing.

Exemplary UV light curing techniques may involve supplying light from one or more UV light sources that shine light onto the substrate. These UV light sources may include a UV lamp that emits light over a broad spectrum of wavelengths (including non-UV wavelengths) that has a peak intensity at a UV wavelength (e.g., 220 nm). Examples of UV lamps include xenon lamps (peak emission wavelength at 172 nm), mercury lamps (peak at 243 nm), deuterium lamps (peak at 140 nm), and krypton chloride (KrCl₂) lamps (peak at 222 nm), among other types of UV lamps. Additional UV light sources may include lasers that provide coherent, narrowband UV light to the oxide layer. Laser light sources may include Excimer lasers (e.g., a XeCl, KrF, F₂, etc., excimer laser) and/or appropriate harmonics of solid state lasers (e.g., Nd—YAG lasers). UV light sources may also include diode UV light sources. Filters and/or monochrometers may be used to narrow the wavelength range of the light that reaches the oxide layer. For example, filters may block light with wavelengths less than 170 nm to keep the UV anneal from removing the carbon in the layer.

The flowable film may be exposed to the UV light source from about 10 seconds to about 60 minutes. Typical exposure times may be from about 1 minute to about 10 minutes (e.g., about 2 minutes to about 5 minutes). The temperature of the oxide layer may be about 25° C. to about 900° C. during the UV anneal step. The UV exposure may be done while the oxide layer is in an atmosphere containing helium, argon, N₂, N₂O, ammonia, ozone, H₂O, or mixtures thereof. The pressure of the atmosphere in the chamber during the UV exposure may range from about 1 Torr to about 600 Torr.

Exemplary thermal curing techniques may involve raising the temperature of the initially deposited oxide layer to about 300° C. to about 600° C. (e.g., about 350° C. to about 400° C.; about 380° C., etc.). The thermal anneal environment may include an inert atmosphere of dry nitrogen (N₂), helium, argon, etc., and the chamber pressure may be about 15 mTorr to about 760 Torr (e.g., about 50 Torr). The flowable film may undergo the thermal curing for about 1 minute to about 30 minutes (e.g., about 1 minute), and produce an cured oxide layer with less moisture and a higher hardness than the initially deposited film. The thermal curing conditions are controlled such that a significant amount of carbon is kept in the annealed layer. Thus, the cured dielectric has a constant lower than a fully thermally cured silicon oxide (κ=3.9).

Exemplary plasma curing techniques may involve exposing the wafer substrate to a plasma generated from one or more inert gases such as helium or argon. The plasma may be generated by a capacitively coupled plasma (CCP) or inductively coupled plasma (ICP) source, and may be generated in situ in the reaction chamber. The RF power used to generate the plasma may be about 1000 Watts to about 9600 Watts (e.g., about 1800 Watts), and the plasma pressure in the chamber may be about 2 mTorr to about 50 mTorr (e.g., about 20 mTorr). During the plasma curing, the substrate may be heated from about 350° C. to about 400° C. (e.g., about 380° C.) during the plasma anneal, and the oxide layer may be exposed to the plasma for about 1 to about 10 minutes (e.g., about 3 minutes).

In some embodiments, more than one type of curing technique may be used to cure the flowable film. For example, a two-stage cure may be performed that includes two of the above-listed techniques. Exemplary two-stage cures may include a first thermal stage followed by a second plasma or UV curing stage. They may also include a first UV curing stage followed by a second plasma or thermal curing stage.

### Exemplary Low-κ Dielectric Materials

Following the curing step 108, the low-κ dielectric material is formed. The term “low-κ” refers to the fact that the material has a lower dielectric constant than a pure, thermal silicon oxide layer (i.e., κ˜3.9). Without wishing to be bound by a particular theory, it is believed that the decrease in κ value is due at least in part to pores created by chemical moieties that leave the silicon oxide framework. For example, hydroxyl group may leave the framework as water vapor, and alkyl groups may leave the framework as alcohols. The pores represent an absence of material that lowers the κ value of a theoretically densest silicon oxide (κ˜3.9) to something closer to a vacuum (κ=1). The silicon oxide framework surrounding the pores prevents the material from achieving a κ value of 1, but the pores still help reduce the oxide to a “low-κ” level. Exemplary κ values for low-κ dielectric oxides are typically about 3.0 or less (e.g., a range from about 3.0 to about 2.0).

The increased porosity that lowers the κ value of the silicon oxide also affects its mechanical properties. As the porosity of these materials increase their hardness and Young's Modulus decrease and dimensionally they become less stable. The silicon-and-carbon linkers counter these effects by introducing stronger and stiffer carbon bonds into the silicon oxide framework. In order for the linkers to enhance the mechanical properties more of the carbon in the linkers has to stay in the final material. This can actually increase the κ value of the material, but to a lesser degree than the increases in mechanical stability. Table 1 shows a comparison of κ values, hardness, and Young's Modulus for low-κ dielectric materials made with and without a silicon-and-carbon linker:

TABLE 1
Comparison of Low-K Dielectric Materials Made
With and Without Linkers

| Material | Low-K Dielectric Materials | Low-K Dielectric Material |
|---|---|---|
| Property | Made with Linker | Made without Linker |
| K value | 2.69-2.84 | 2.66 |
| Hardness | 1.8-2.5 GPa | 1.3 GPa |
| Young's | 11-15 GPa | 7.6 GPa |
| Modulus | | |

The examples in Table 1 show κ values for the present low-κ dielectric materials may be about 3.5 or less (e.g., about 2.85 to about 2.65). Exemplary hardness for the low-κ dielectric material may be about 1.4 GPa or more, and in some cases about 1.8 GPa or more. Exemplary Young's Modulus values for the low-κ dielectric material may be about 7.8 GPa or more, and in some cases about 11 GPa or more. Comparative low-κ dielectric material samples that do not include a silicon-and-carbon containing linker typically have hardness values of less than 1.3 GPa and Young's Modulus values of less than 7.6 GPa while having only slightly lower κ values.

The carbon content (on an atomic percentage basis) of the low-κ dielectric material may be about 3% or more (e.g, about 3% to about 5%) in disclosed embodiments. In some instances, the atomic percentage of carbon content may greater than 8%.

### Exemplary Deposition Systems

Deposition chambers that may implement embodiments of the present invention may include flowable chemical vapor deposition chambers (FCVD), high-density plasma chemical vapor deposition (HDP-CVD) chambers, plasma enhanced chemical vapor deposition (PECVD) chambers, sub-atmospheric chemical vapor deposition (SACVD) chambers, and thermal chemical vapor deposition chambers, among other types of chambers. Specific examples of CVD systems that may implement embodiments of the invention include the PRODUCER ETERNA® FCVD chambers/systems, CENTURA ULTIMA® HDP-CVD chambers/systems, and PRODUCER® PECVD chambers/systems, available from Applied Materials, Inc. of Santa Clara, Calif.

Examples of substrate processing chambers that can be used with exemplary methods of the invention may include those shown and described in co-assigned U.S. Provisional Patent App. No. 60/803,499 to Lubomirsky et al, filed May 30, 2006, and titled “PROCESS CHAMBER FOR DIELECTRIC GAPFILL,” the entire contents of which is herein incorporated by reference for all purposes. Additional exemplary systems may include those shown and described in U.S. Pat. Nos. 6,387,207 and 6,830,624, which are also incorporated herein by reference for all purposes.

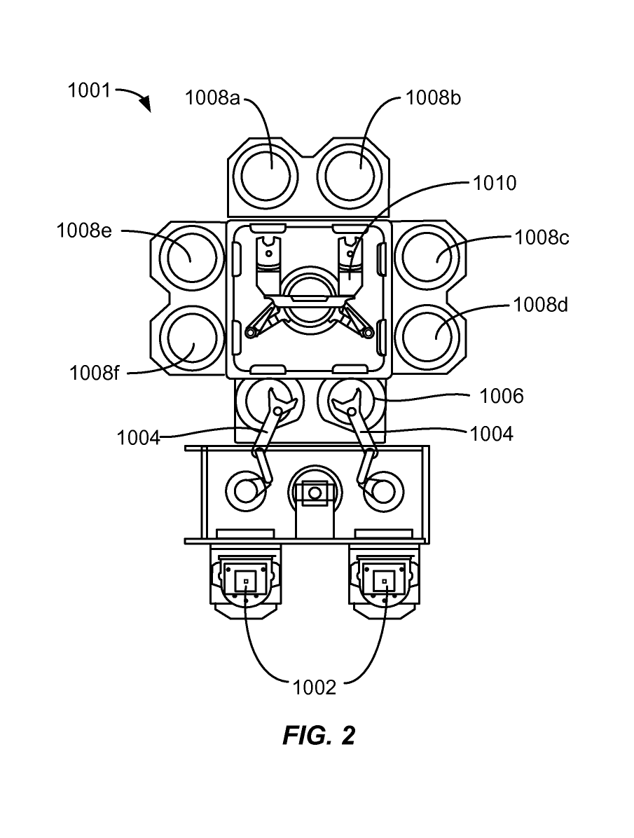

Embodiments of the deposition systems may be incorporated into larger fabrication systems for producing integrated circuit chips. FIG. 2 shows one such system 1001 of deposition, baking and curing chambers according to disclosed embodiments. In the figure, a pair of FOUPs (front opening unified pods) 1002 supply substrate substrates (e.g., 300 mm diameter wafers) that are received by robotic arms 1004 and placed into a low pressure holding area 1006 before being placed into one of the wafer processing chambers 1008a-f. A second robotic arm 1010 may be used to transport the substrate wafers from the holding area 1006 to the processing chambers 1008a-f and back.

The processing chambers 1008a-f may include one or more system components for depositing, annealing, curing and/or etching a flowable dielectric film on the substrate wafer. In one configuration, two pairs of the processing chamber (e.g., 1008c-d and 1008e-f) may be used to deposit the flowable dielectric material on the substrate, and the third pair of processing chambers (e.g., 1008a-b) may be used to anneal the deposited dielectric. In another configuration, the same two pairs of processing chambers (e.g., 1008c-d and 1008e-f) may be configured to both deposit and anneal a flowable dielectric film on the substrate, while the third pair of chambers (e.g., 1008a-b) may be used for UV or E-beam curing of the deposited film. In still another configuration, all three pairs of chambers (e.g., 1008a-f) may be configured to deposit and cure a flowable dielectric film on the substrate. In yet another configuration, two pairs of processing chambers (e.g., 1008c-d and 1008e-f) may be used for both deposition and UV or E-beam curing of the flowable dielectric, while a third pair of processing chambers (e.g. 1008a-b) may be used for annealing the dielectric film. Any one or more of the processes described may be carried out on chamber(s) separated from the fabrication system shown in different embodiments.

In addition, one or more of the process chambers 1008a-f may be configured as a wet treatment chamber. These process chambers include heating the flowable dielectric film in an atmosphere that includes moisture. Thus, embodiments of system 1001 may include wet treatment chambers 1008a-b and anneal processing chambers 1008c-d to perform both wet and dry anneals on the deposited dielectric film.

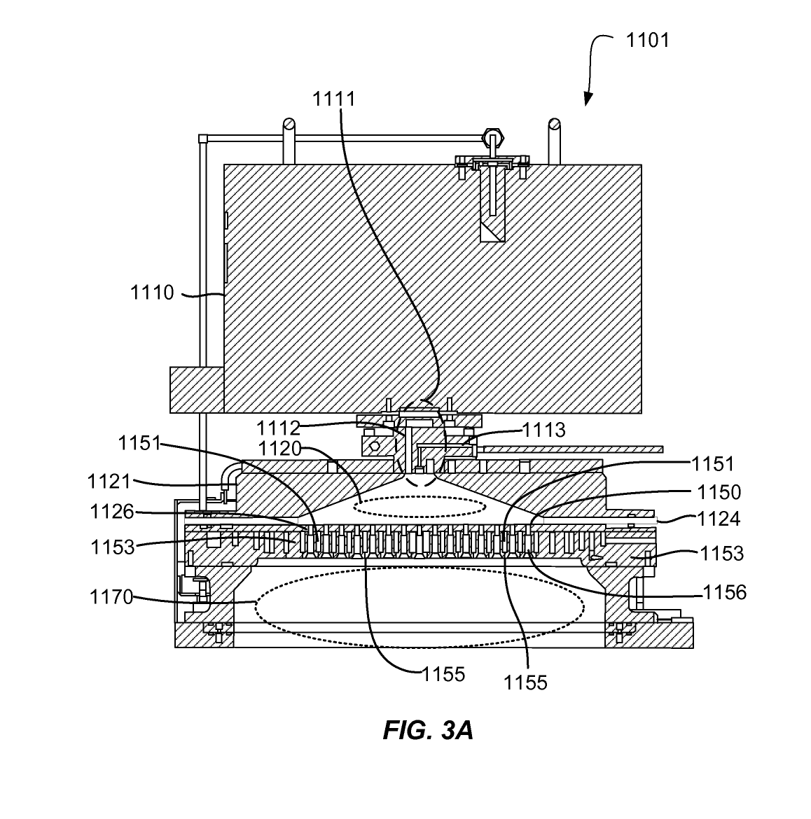

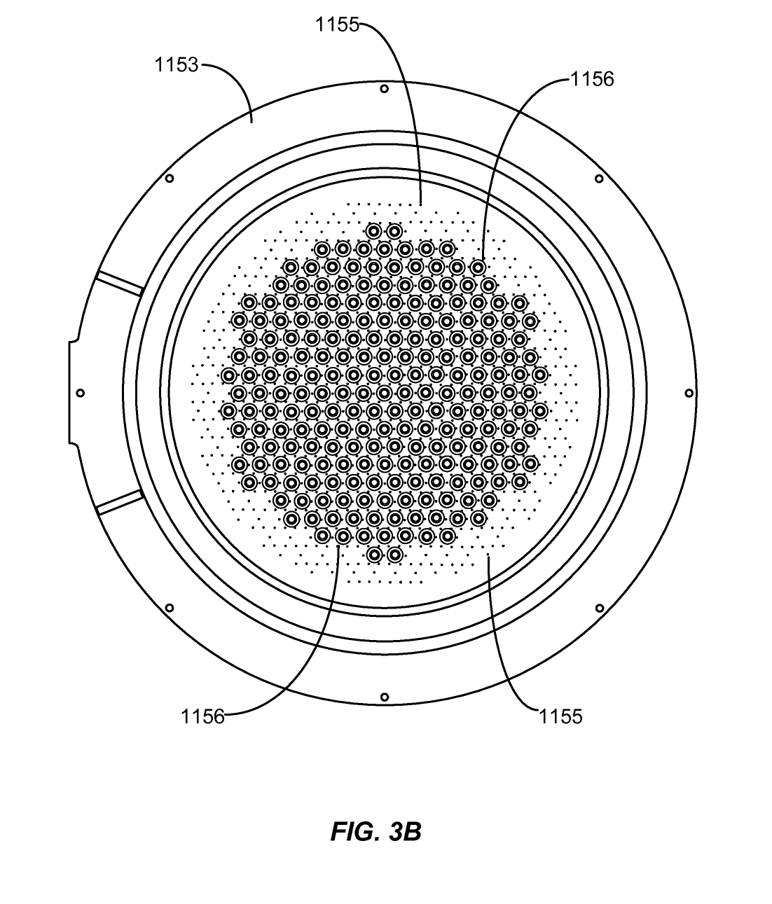

FIG. 3A is a substrate processing chamber 1101 according to disclosed embodiments. A remote plasma system (RPS) 1110 may process a gas which then travels through a gas inlet assembly 1111. Two distinct gas supply channels are visible within the gas inlet assembly 1111. A first channel 1112 carries a gas that passes through the remote plasma system (RPS) 1110, while a second channel 1113 bypasses the RPS 1110. The first channel 1112 may be used for the process gas and the second channel 1113 may be used for a treatment gas in disclosed embodiments. The lid (or conductive top portion) 1121 and a perforated partition 1153 are shown with an insulating ring 1124 in between, which allows an AC potential to be applied to the lid 1121 relative to perforated partition 1153. The process gas travels through first channel 1112 into chamber plasma region 1120 and may be excited by a plasma in chamber plasma region 1120 alone or in combination with RPS 1110. The combination of chamber plasma region 1120 and/or RPS 1110 may be referred to as a remote plasma system herein. The perforated partition (also referred to as a showerhead) 1153 separates chamber plasma region 1120 from a substrate processing region 1170 beneath showerhead 1153. Showerhead 1153 allows a plasma present in chamber plasma region 1120 to avoid directly exciting gases in substrate processing region 1170, while still allowing excited species to travel from chamber plasma region 1120 into substrate processing region 1170.

Showerhead 1153 is positioned between chamber plasma region 1120 and substrate processing region 1170 and allows plasma effluents (excited derivatives of precursors or other gases) created within chamber plasma region 1120 to pass through a plurality of through holes 1156 that traverse the thickness of the plate. The showerhead 1153 also has one or more hollow volumes 1151 which can be filled with a precursor in the form of a vapor or gas (such as a silicon-and-carbon-containing precursor) and pass through small holes 1155 into substrate processing region 1170 but not directly into chamber plasma region 1120. Showerhead 1153 is thicker than the length of the smallest diameter 1150 of the through-holes 1156 in this disclosed embodiment. In order to maintain a significant concentration of excited species penetrating from chamber plasma region 1120 to substrate processing region 1170, the length 1126 of the smallest diameter 1150 of the through-holes may be restricted by forming larger diameter portions of through-holes 1156 part way through the showerhead 1153. The length of the smallest diameter 1150 of the through-holes 1156 may be the same order of magnitude as the smallest diameter of the through-holes 1156 or less in disclosed embodiments.

In the embodiment shown, showerhead 1153 may distribute (via through holes 1156) process gases which contain oxygen and/or plasma effluents of process gases upon excitation by a plasma in chamber plasma region 1120. In embodiments, the process gas introduced into the RPS 1110 and/or chamber plasma region 1120 through first channel 1112 may contain one or more of oxygen (O₂), ozone (O₃), N₂O, NO, and NO₂. However, the oxygen-containing precursor may be devoid of nitrogen, the remote plasma region may be devoid of nitrogen, and the resulting Si—O—C film may commensurately be devoid of nitrogen, in disclosed embodiments. The process gas may also include a carrier gas such as helium, argon, nitrogen (N₂), etc. The second channel 1113 may also deliver a process gas and/or a carrier gas, and/or a film-curing gas (e.g. O₃) used to remove an unwanted component from the growing or as-deposited film. Plasma effluents may include ionized or neutral derivatives of the process gas and may also be referred to herein as a radical-oxygen precursor referring to the atomic constituent of the process gas introduced.

In embodiments, the number of through-holes 1156 may be between about 60 and about 2000. Through-holes 1156 may have a variety of shapes but are most easily made round. The smallest diameter 1150 of through holes 1156 may be between about 0.5 mm and about 20 mm or between about 1 mm and about 6 mm in disclosed embodiments. There is also latitude in choosing the cross-sectional shape of through-holes, which may be made conical, cylindrical or a combination of the two shapes. The number of small holes 1155 used to introduce a gas into substrate processing region 1170 may be between about 100 and about 5000 or between about 500 and about 2000 in different embodiments. The diameter of the small holes 1155 may be between about 0.1 mm and about 2 mm.

FIG. 3B is a bottom view of a showerhead 1153 for use with a processing chamber according to disclosed embodiments. Showerhead 1153 corresponds with the showerhead shown in FIG. 3A. Through-holes 1156 are depicted with a larger inner-diameter (ID) on the bottom of showerhead 1153 and a smaller ID at the top. Small holes 1155 are distributed substantially evenly over the surface of the showerhead, even amongst the through-holes 1156 which helps to provide more even mixing than other embodiments described herein.

An exemplary film is created on a substrate supported by a pedestal (not shown) within substrate processing region 1170 when plasma effluents arriving through through-holes 1156 in showerhead 1153 combine with a silicon-and-carbon-containing precursor arriving through the small holes 1155 originating from hollow volumes 1151. Though substrate processing region 1170 may be equipped to support a plasma for other processes such as curing, no plasma is present during the growth of the exemplary film.

A plasma may be ignited either in chamber plasma region 1120 above showerhead 1153 or substrate processing region 1170 below showerhead 1153. A plasma is present in chamber plasma region 1120 to produce the radical-oxygen precursor from an inflow of an oxygen-containing gas. An AC voltage typically in the radio frequency (RF) range is applied between the conductive top portion 1121 of the processing chamber and showerhead 1153 to ignite a plasma in chamber plasma region 1120 during deposition. An RF power supply generates a high RF frequency of 13.56 MHz but may also generate other frequencies alone or in combination with the 13.56 MHz frequency. Exemplary RF frequencies include microwave frequencies such as 2.4 GHz. The top plasma power may be greater than or about 1000 Watts, greater than or about 2000 Watts, greater than or about 3000 Watts or greater than or about 4000 Watts in embodiments of the invention, during deposition of the flowable film.

The top plasma may be left at low or no power when the bottom plasma in the substrate processing region 1170 is turned on during the second curing stage or clean the interior surfaces bordering substrate processing region 1170. A plasma in substrate processing region 1170 is ignited by applying an AC voltage between showerhead 1153 and the pedestal or bottom of the chamber. A cleaning gas may be introduced into substrate processing region 1170 while the plasma is present.

The pedestal may have a heat exchange channel through which a heat exchange fluid flows to control the temperature of the substrate. This configuration allows the substrate temperature to be cooled or heated to maintain relatively low temperatures (from room temperature through about 120° C.). The heat exchange fluid may comprise ethylene glycol and water. The wafer support platter of the pedestal (preferably aluminum, ceramic, or a combination thereof) may also be resistively heated in order to achieve relatively high temperatures (from about 120° C. through about 1100° C.) using an embedded single-loop embedded heater element configured to make two full turns in the form of parallel concentric circles. An outer portion of the heater element may run adjacent to a perimeter of the support platter, while an inner portion runs on the path of a concentric circle having a smaller radius. The wiring to the heater element passes through the stem of the pedestal.

The substrate processing system is controlled by a system controller. In an exemplary embodiment, the system controller includes a hard disk drive, a floppy disk drive and a processor. The processor contains a single-board computer (SBC), analog and digital input/output boards, interface boards and stepper motor controller boards. Various parts of CVD system conform to the Versa Modular European (VME) standard which defines board, card cage, and connector dimensions and types. The VME standard also defines the bus structure as having a 16-bit data bus and a 24-bit address bus.

The system controller controls all of the activities of the deposition system. The system controller executes system control software, which is a computer program stored in a computer-readable medium. Preferably, the medium is a hard disk drive, but the medium may also be other kinds of memory. The computer program includes sets of instructions that dictate the timing, mixture of gases, chamber pressure, chamber temperature, RF power levels, susceptor position, and other parameters of a particular process. Other computer programs stored on other memory devices including, for example, a floppy disk or other another appropriate drive, may also be used to instruct the system controller.

A process for depositing a film stack (e.g. sequential deposition of a silicon-oxygen-and-hydrogen-containing layer and then a silicon-oxygen-and-carbon-containing layer) on a substrate, converting a film to silicon oxide or a process for cleaning a chamber can be implemented using a computer program product that is executed by the system controller. The computer program code can be written in any conventional computer readable programming language: for example, 68000 assembly language, C, C++, Pascal, Fortran or others. Suitable program code is entered into a single file, or multiple files, using a conventional text editor, and stored or embodied in a computer usable medium, such as a memory system of the computer. If the entered code text is in a high level language, the code is compiled, and the resultant compiler code is then linked with an object code of precompiled Microsoft Windows® library routines. To execute the linked, compiled object code the system user invokes the object code, causing the computer system to load the code in memory. The CPU then reads and executes the code to perform the tasks identified in the program.

The interface between a user and the controller is via a flat-panel touch-sensitive monitor. In the preferred embodiment two monitors are used, one mounted in the clean room wall for the operators and the other behind the wall for the service technicians. The two monitors may simultaneously display the same information, in which case only one accepts input at a time. To select a particular screen or function, the operator touches a designated area of the touch-sensitive monitor. The touched area changes its highlighted color, or a new menu or screen is displayed, confirming communication between the operator and the touch-sensitive monitor. Other devices, such as a keyboard, mouse, or other pointing or communication device, may be used instead of or in addition to the touch-sensitive monitor to allow the user to communicate with the system controller.

As used herein “substrate” may be a support substrate with or without layers formed thereon. The support substrate may be an insulator or a semiconductor of a variety of doping concentrations and profiles and may, for example, be a semiconductor substrate of the type used in the manufacture of integrated circuits. The term “precursor” is used to refer to any process gas which takes part in a reaction to either remove material from or deposit material onto a surface. A gas in an “excited state” describes a gas wherein at least some of the gas molecules are in vibrationally-excited, dissociated and/or ionized states. A gas (or precursor) may be a combination of two or more gases (or precursors). A “radical precursor” is used to describe plasma effluents (a gas in an excited state which is exiting a plasma) which participate in a reaction to either remove material from or deposit material on a surface. A “radical-oxygen precursor” is a radical precursor which contains oxygen and may be nitrogen-free in embodiments. The phrase “inert gas” refers to any gas which does not form chemical bonds when etching or being incorporated into a film. Exemplary inert gases include noble gases but may include other gases so long as no chemical bonds are formed when (typically) trace amounts are trapped in a film.

The terms “gap” or “trench” are used throughout with no implication that the etched geometry has a large horizontal aspect ratio. Viewed from above the surface, gaps and trenches may appear circular, oval, polygonal, rectangular, or a variety of other shapes. As used herein, a conformal layer refers to a generally uniform layer of material on a surface in the same shape as the surface, i.e., the surface of the layer and the surface being covered are generally parallel. A person having ordinary skill in the art will recognize that the deposited material likely cannot be 100% conformal and thus the term “generally” allows for acceptable tolerances.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the precursor” includes reference to one or more precursors and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A method of forming a low-κ dielectric material on a substrate, the method comprising:
producing a radical precursor by flowing an unexcited precursor into a remote plasma region;
reacting the radical precursor with a gas-phase silicon precursor and depositing a flowable film on the substrate, wherein the gas-phase silicon precursor comprises at least one silicon-and-oxygen containing compound and at least one silicon-and-carbon linker; and
curing the flowable film to form the low-κ dielectric material.

2. The method of claim 1, wherein the at least one silicon-and-carbon linker has a formula chosen from: 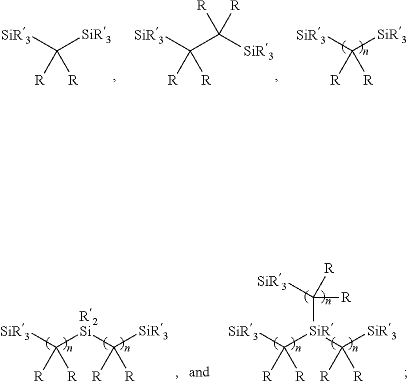
wherein R may each independently be an alkyl moiety, a silyl moiety, an alkoxyl moiety, or a hydrogen (H) moiety;
R′ may each independly be an alkyl moiety, a silyl moiety, or a hydrogen moiety; and
each n may independently be a whole number from 0 to 10, with at least one n value being greater than 0.

3. The method of claim 1, wherein at least one silicon-and-carbon linker is chosen from 1,3,5-trisilapentane, 1,4,7-trisilaheptane, disilacyclobutane, trisilacyclohexane, 1,4-disilabutane, disilacyclohexane, disilacyclopentane, and disilapropane.

4. The method of claim 1, wherein the at least one silicon-and-carbon linker comprises a homocyclic or a hetrocyclic compound.

5. The method of claim 1, wherein the silicon-and-carbon linker increases hardness of the low-κ dielectric material.

6. The method of claim 1, wherein the low-κ dielectric material has a hardness of about 1.4 GPa or more.

7. The method of claim 1, wherein the low-κ dielectric material has a hardness of about 1.8 GPa or more.

8. The method of claim 1, wherein the low-κ dielectric material has a Young's Modulus of about 7.8 GPa or more.

9. The method of claim 1, wherein the low-κ dielectric material has a Young's Modulus of about 11 GPa or more.

10. The method of claim 1, wherein the low-κ dielectric material has a κ value of about 3.5 or less.

11. The method of claim 1, wherein the low-κ dielectric material has a κ value from about 2.85 to about 2.65.

12. The method of claim 1, wherein the radical precursor comprises a radical oxygen precursor.

13. The method of claim 1, wherein gas-phase silicon precursor includes one or more silicon compounds chosen from a siloxane and a silicate.

14. The method of claim 13, wherein the siloxane comprises octamethylcyclotetrasiloxane or octamethyltrisiloxane.

15. The method of claim 13, wherein the silicate comprises an alkylorthosilicate.

16. The method of claim 15, wherein the alkylorthosilicate comprises tetramethylorthosilicate or tetraethylorthosilicate.

17. The method of claim 1, wherein the gas-phase silicon precursor further comprises a substituted or unsubstituted silicon compound.

18. The method of claim 17, wherein the substituted or unsubstituted silicon compound comprises a silane, an ammonia-substituted silane, or a halogen-substituted silane.

19. The method of claim 1, wherein the curing step is chosen from
i) exposing the flowable film to an ultraviolet source, an e-beam source, or a neutral beam source;
ii) thermal curing the flowable film at an elevated temperature;
iii) microwave curing the flowable film; and
iv) exposing the flowable film to a plasma.

20. The method of claim 1, wherein the curing step comprises two or more curing steps.
